(19) United States
(12) Patent Application Publication
(10) Pub. No.: US 2025/0029906 A1
(43) Pub. Date: Jan. 23, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Kyounglim Suk, Suwon-si (KR); Kimin Cheong, Suwon-si (KR); Hyeonjeong Hwang, Suwon-si (KR)

(21) Appl. No.: 18/646,834

(22) Filed: Apr. 26, 2024

(30) Foreign Application Priority Data
Jul. 21, 2023 (KR) 10-2023-0095615

(51) Int. Cl. H01L 23/498; H01L 23/00; H01L 23/31; H01L 23/522; H01L 25/00; H01L 25/18

(52) U.S. Cl. CPC H01L 23/49822; H01L 23/3128; H01L 23/49833; H01L 23/49838; H01L 23/49866; H01L 23/5226; H01L 24/06; H01L 24/08; H01L 25/18; H01L 24/16; H01L 25/50; H01L 2224/06051; H01L 2224/08225; H01L 2224/16225; H01L 2225/06517; H01L 2924/1431

(57) ABSTRACT

Provided are a semiconductor package including a pad with high reliability and a method of manufacturing the semiconductor package. The semiconductor package includes a first redistribution substrate, a semiconductor chip on the first redistribution substrate, a through post extending around the semiconductor chip and on the first redistribution substrate, and a second redistribution substrate on the semiconductor chip and the through post. A first pad region and a second pad region are defined on an upper surface of the second redistribution substrate, the first pad region positioned at a central portion of the second redistribution substrate, and the second pad region extending around the first pad region, a first-type pad in a planar shape is in a first opening, a second-type pad having an outer protruding portion is in a second opening.

### CROSS-REFERENCE TO RELATED APPLICATION(S)

This application is based on and claims priority under 35 U.S.C. § 119 to Korean Patent Application No. 10-2023-0095615, filed on Jul. 21, 2023, in the Korean Intellectual Property Office, the disclosure of which is incorporated by reference herein in its entirety.

### BACKGROUND

The inventive concept relates generally to a semiconductor package, and more particularly, to a semiconductor package including redistribution substrates respectively on upper and lower portions of a semiconductor chip, and a method of manufacturing the semiconductor package.

According to the rapid development of the electronics industry and user demands, electronic devices have further decreased in size and weight. As the size and weight of electronic devices are reduced, semiconductor packages used therein also have reduced in size and weight, and the semiconductor packages are also required to have high reliability together with high performance and large capacity. As these semiconductor packages become more high-performance and high-capacity, power consumption of the semiconductor packages has increased. Accordingly, the importance of a structure of a semiconductor package, which corresponds to the size/performance of the semiconductor package and provides stable power supply to the semiconductor package, has increased.

### SUMMARY

The inventive concept provides a semiconductor package including a pad with high reliability, and a method of manufacturing the semiconductor package.

According to an aspect of the inventive concept, there is provided a semiconductor package including a first redistribution substrate having a multi-layered first redistribution line, a semiconductor chip on the first redistribution substrate, a through post extending around the semiconductor chip and on the first redistribution substrate, and a second redistribution substrate on the semiconductor chip and the through post and having a multi-layered second redistribution line. A first pad region and a second pad region are defined on an upper surface of the second redistribution substrate, the first pad region in which a first opening exposing a portion of the second redistribution line is arranged and being positioned at a central portion of the second redistribution substrate, and the second pad region surrounding (i.e., extending around) the first pad region and in which a second opening exposing a portion of the second redistribution line is arranged, a first-type pad in a flat shape is arranged on the second redistribution line in the first opening, and a second-type pad having an outer protruding portion is on the second redistribution line in the second opening.

According to another aspect of the inventive concept, there is provided a semiconductor package including a first redistribution substrate having a multi-layered first redistribution line, a semiconductor chip on the first redistribution substrate, a sealing material on the first redistribution substrate to cover the semiconductor chip, a through post extending around the semiconductor chip on the first redistribution substrate in a structure of penetrating the sealing material, a second redistribution substrate on the sealing material and having a multi-layered second redistribution line, and an upper package on the second redistribution substrate through an inter-substrate connection terminal. An opening exposing a portion of the second redistribution line is on an upper surface of the second redistribution substrate, and an uppermost second redistribution line exposed from the opening has a multi-metal-layered structure.

According to another aspect of the inventive concept, there is provided a semiconductor package including a first redistribution substrate having a multi-layered first redistribution line, a semiconductor chip on the first redistribution substrate, a through post extending around the semiconductor chip and on the first redistribution substrate, and a second redistribution substrate on the semiconductor chip and the through post and having a multi-layered second redistribution line. An opening exposing a portion of the second redistribution line is on an upper surface of the second redistribution substrate, and an uppermost second redistribution line exposed from the opening includes a lower metal layer of copper (Cu) and an upper metal layer of nickel (Ni).

According to another aspect of the inventive concept, there is provided a method of manufacturing a semiconductor package, the method including forming a first redistribution substrate on a carrier substrate, forming a through post on an outer portion of the first redistribution substrate, mounting a semiconductor chip on a central portion of the first redistribution substrate, forming a sealing material covering the through post and the semiconductor chip, exposing an upper surface of the through post by grinding an upper portion of the sealing material, and forming a second redistribution substrate on the through post and the sealing material. The forming of the second redistribution substrate includes forming an uppermost redistribution line having a lower metal layer of copper (Cu) and an upper metal layer of nickel (Ni) through electroplating, forming a body insulating layer covering the uppermost redistribution line, forming an open hole penetrating the body insulating layer to expose a portion of the uppermost redistribution line, and forming two types of pads on the uppermost redistribution line in the open hole.

### BRIEF DESCRIPTION OF THE DRAWINGS

Embodiments of the inventive concept will be more clearly understood from the following detailed description taken in conjunction with the accompanying drawings, wherein like reference numerals (when used) indicate corresponding elements throughout the several views, and in which:

FIGS. 1A and 1B are a plan view and a cross-sectional view, respectively, each schematically showing an example structure of a semiconductor package according to an embodiment of the present disclosure;

FIGS. 2A to 2C are cross-sectional views showing an enlarged region EP of the semiconductor package of FIG. 1B;

FIG. 3 is a cross-sectional view showing an enlarged region A of FIG. 2A;

FIG. 4 is a partial cross-sectional view of a semiconductor package of a comparative example;

FIGS. 5A to 5D are cross-sectional views each schematically showing an example structure of a semiconductor package according to an embodiment of the present disclosure;

FIG. 6 is a cross-sectional view showing in more detail an example structure of an upper package in the semiconductor package of FIG. 5A;

FIGS. 7A to 7J are cross-sectional views schematically showing intermediate processes in an example operation of manufacturing the semiconductor package of FIG. 1B; and

FIGS. 8A to 8D are cross-sectional views showing in more detail intermediate processes in an example operation of manufacturing a second redistribution substrate of FIG. 7J.

### DETAILED DESCRIPTION

The inventive concept will now be described more fully with reference to the accompanying drawings, in which embodiments of the inventive concept are shown. As previously stated, like reference numerals in the drawings denote like elements, and thus their description will be omitted.

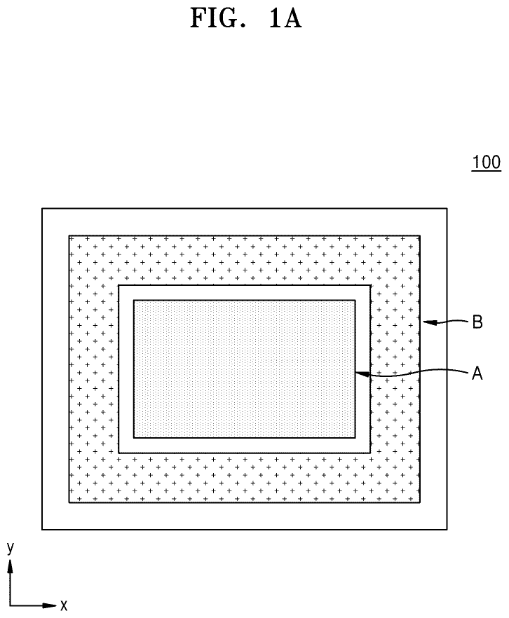

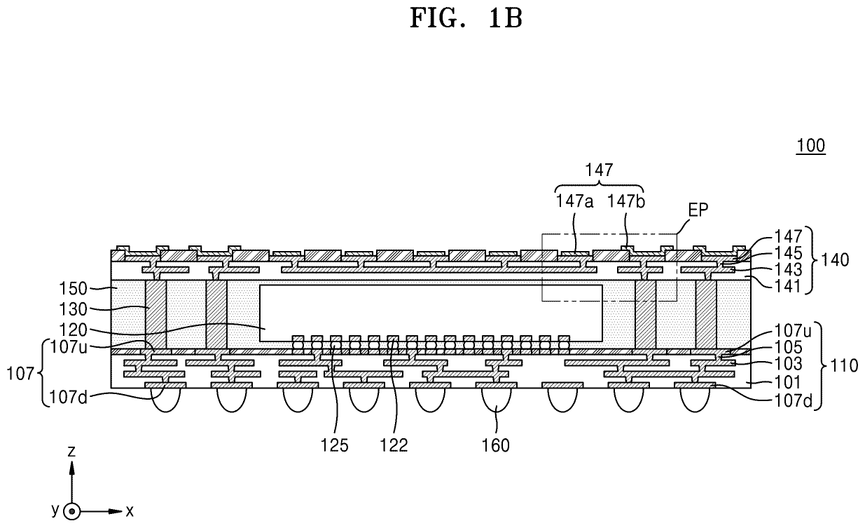

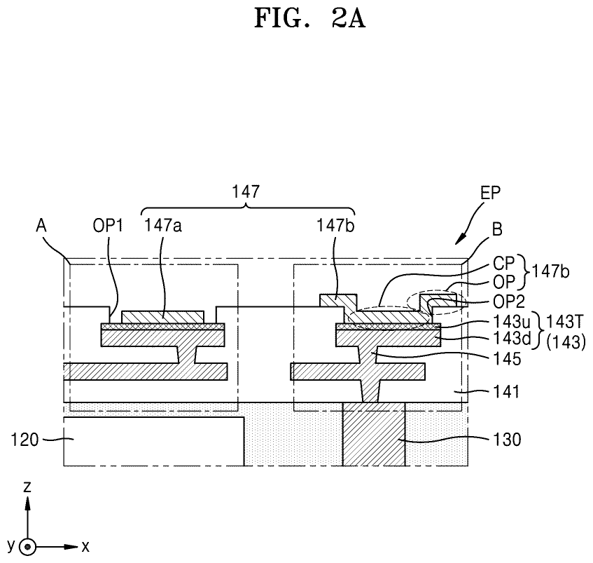

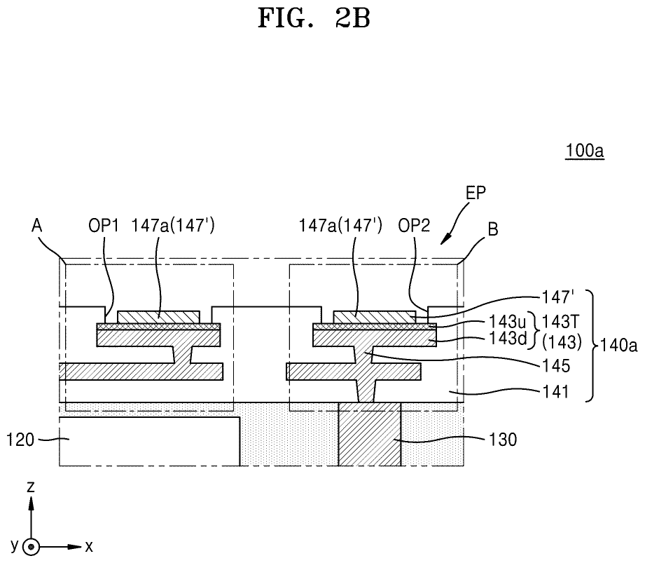

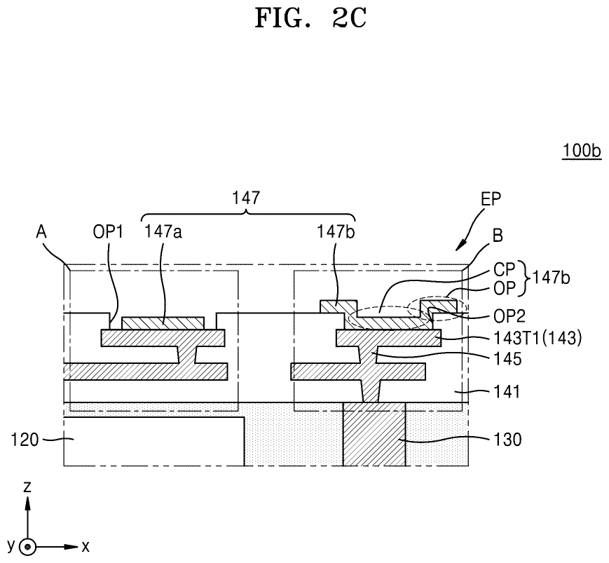

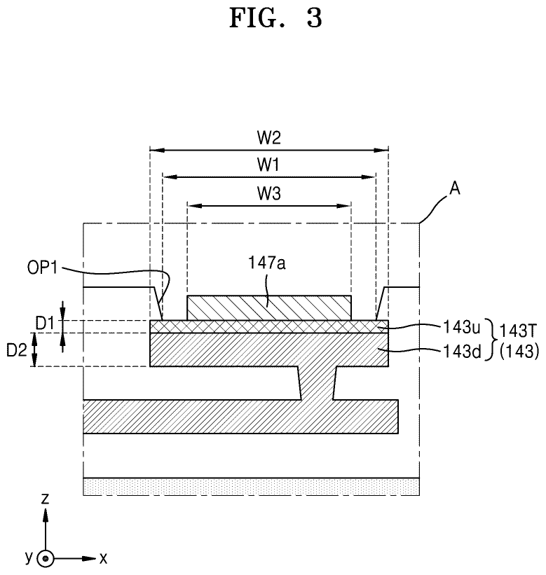

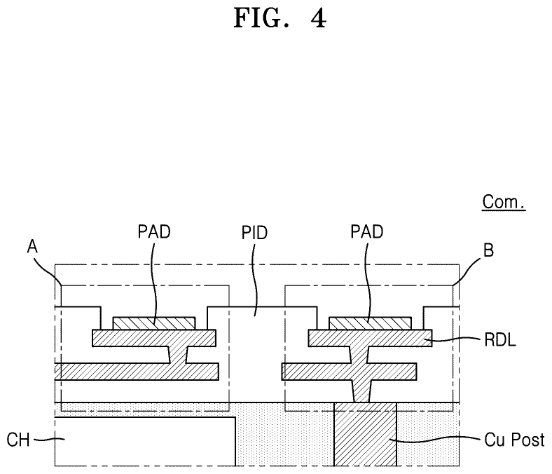

FIGS. 1A and 1B are a plan view and a cross-sectional view, respectively, each schematically showing an example structure of a semiconductor package according to an embodiment of the present disclosure, and FIGS. 2A to 2C are cross-sectional views showing an enlarged region EP of the semiconductor package of FIG. 1B. FIG. 3 is a cross-sectional view showing an enlarged region A of FIG. 2A. FIG. 4 is a partial cross-sectional view of a semiconductor package of a comparative example.

Referring to FIGS. 1A to 2A and 3, a semiconductor package 100 according to an embodiment may include a first redistribution substrate 110, a semiconductor chip 120, a through post 130, a second redistribution substrate 140, a sealing material (i.e., encapsulant) 150, and an external connection terminal 160. The semiconductor package 100 of the embodiment may be a wafer-level package (WLP).

The first redistribution substrate 110 may be arranged on a lower portion of the semiconductor chip 120 and functions to redistribute an electrical connection to a chip pad 122 of the semiconductor chip 120 to an external region of the semiconductor chip 120. In particular, the first redistribution substrate 110 may include a first body insulating layer 101, a first redistribution line 103, a first vertical via 105, and a first substrate pad 107, the first substrate pad 107 including a first lower substrate pad 107d and a first upper substrate pad 107u.

The first body insulating layer 101 may include an insulating material, for example, a photo-imageable dielectric (PID) resin, and may further include an inorganic filler. However, the material of the first body insulating layer 101 is not limited to a PID. The first body insulating layer 101 may have a multi-layered structure according to a multi-layered structure of the first redistribution line 103. However, in FIG. 1B, for convenience, the first body insulating layer 101 is illustrated as a single-layered structure.

The first redistribution line 103 may be configured as a multi-layered structure within the first body insulating layer 101. First redistribution lines 103 of different layers may be connected to each other through corresponding first vertical vias 105. Also, the first redistribution line 103 may be connected to a first substrate pad 107 through the first vertical via 105. The first substrate pad 107 may include the first lower substrate pad 107d on a lower surface of the first body insulating layer 101 and the first upper substrate pad 107u on an upper surface of the first body insulating layer 101.

The external connection terminal 160 may be on the lower surface of the first body insulating layer 101. The external connection terminal 160 may be on the first lower substrate pad 107d on the lower surface of the first body insulating layer 101. The external connection terminal 160 may be electrically connected to the semiconductor chip 120 through the first redistribution line 103 of the first redistribution substrate 110 and one or more bumps 125. The term “connection” (or “connecting,” “contact,” “contacting,” or like terms), as may be used herein, is intended to refer to a physical and/or electrical connection between two or more elements, and may include other intervening elements. As used herein, the term “and/or” includes any and all combinations of one or more of the associated listed items.

The external connection terminal 160 may be at a central lower surface portion of the first redistribution substrate 110 and an outer lower surface portion of the first redistribution substrate 110, the central lower surface portion corresponding to a lower surface of the semiconductor chip 120, and the outer lower surface portion extending from the central lower surface portion to the outside in a first direction (x direction) and a second direction (y direction), the first direction intersecting the second direction, and first and second directions being parallel to an upper surface of the first redistribution substrate 110. As a result, the first redistribution substrate 110 may function to redistribute electrical connection to the bumps 125 of the semiconductor chip 120 to a portion wider than the lower surface of the semiconductor chip 120 through the first redistribution line 103 and the external connection terminal 160. As such, a package structure in which the external connection terminal 160 is in a wider region than the lower surface of the semiconductor chip 120 is referred to as a fan-out (FO) package structure. On the contrary, a package structure in which the external connection terminal 160 is only arranged at a portion corresponding to the lower surface of the semiconductor chip 120 is referred to as a fan-in (FI) package structure.

The semiconductor chip 120 may be disposed on the first redistribution substrate 110 through the one or more bumps 125. The semiconductor chip 120 may be at a central portion of the first redistribution substrate 110 in the x direction. Also, the semiconductor chip 120 may be arranged at a central portion of the first redistribution substrate 110 in the y direction. The bump(s) 125 may include a metal pillar. In some embodiments, the bump 125 may include a metal pillar and a solder. Here, the metal pillar may include, for example, copper (Cu). However, the material of the metal pillar is not limited to Cu.

The semiconductor chip 120 may be an analog chip. The semiconductor chip 120 may include a plurality of logic elements therein. Here, a logic element is an element performing various logic processing and may include, for example, an AND, an OR, a NOT, a flip-flop, or the like. The logic element may also include elements for supporting communication. In the semiconductor package 100 of the embodiment, the semiconductor chip 120 may be, for example, an application processor (AP) chip. The semiconductor chip 120 may also be referred to as a control chip, a process chip, a central processing unit (CPU) chip, or the like, according to a function thereof. Also, in the aspect of integrated functionality, the semiconductor chip 120 is also referred to as a system-on-chip (SoC). According to embodiments, elements for supporting communication may be separately provided in a modem chip, or may be arranged on the first redistribution substrate 110 in a structure coupled to the semiconductor chip 120.

The semiconductor chip 120 may include a substrate and multiple wire layers. An integrated circuit layer may be formed on an active surface of the substrate. The integrated circuit layer may include multiple logic elements. The multiple wire layers may be arranged on a lower surface of the substrate and include multiple layers of wire lines. In the semiconductor chip 120, the lower surface may be a front side that is an active surface and the upper surface may be a back side that is an inactive surface. In other words, based on the substrate (and depending on an orientation of the semiconductor chip 120 in the semiconductor package 100), the lower surface of the substrate, on which multiple wire layers are arranged, may correspond to the front side of the semiconductor chip 120, and the upper surface of the substrate may correspond to the back side of the semiconductor chip 120. The semiconductor chip 120 may be mounted on the first redistribution substrate 110 in a flip-chip structure through the chip pad 122 and the bump 125 arranged on the front side of the semiconductor chip 120.

The through post 130 may extend in the z direction between the first redistribution substrate 110 and the second redistribution substrate 140. The sealing material 150 may be arranged between the first redistribution substrate 110 and the second redistribution substrate 140. Accordingly, the through post 130 may have a structure extending through the sealing material 150. The through post 130 may electrically connect the first redistribution substrate 110 to the second redistribution substrate 140. For example, the through post 130 may be connected to the first redistribution line 103 of the first redistribution substrate 110 and also be connected to a second redistribution line 143 of the second redistribution substrate 140.

The through post 130 may include, for example, Cu. However, the material of the through post 130 is not limited to Cu. The through post 130 may be formed through electroplating using a seed metal. Accordingly, the seed metal may be formed on the first redistribution substrate 110, and the through post 130 may be formed on the seed metal. The seed metal may include, for example, various metal materials, such as Cu, titanium (Ti), tantalum (Ta), titanium nitride (TiN), tantalum nitride (TaN), or the like. In the semiconductor package 100 of the embodiment, the seed metal may be included as a portion of the through post 130. For example, the seed metal may include Cu, and the through post 130 may also include Cu. Accordingly, in FIG. 1B, the seed metal is not separately indicated.

The sealing material 150 may cover and seal side and upper surfaces of the semiconductor chip 120. Also, the sealing material 150 may surround a side surface of the through post 130. The term “cover” (or “covering”, or like terms), as may be used herein, is intended to broadly refer to an element, structure or layer that is on or over another element, structure or layer, either directly or with one or more other intervening elements, structures or layers therebetween. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. As shown in FIG. 1B, the sealing material 150 may also be between the upper surface of the semiconductor chip 120 and a lower surface of the second redistribution substrate 140. However, according to embodiments, the sealing material 150 may not be between the upper surface of the semiconductor chip 120 and the lower surface of the second redistribution substrate 140. That is, according to embodiments, the upper surface of the semiconductor chip 120 may be in direct contact (i.e., without intervening elements) with the lower surface of the second redistribution substrate 140.

As shown in FIG. 1B, the sealing material 150 may fill a space between the first redistribution substrate 110 and the semiconductor chip 120 and between bumps 125 on the lower surface of the semiconductor chip 120. However, in some embodiments, an underfill is filled between the bumps 125 on the lower surface of the semiconductor chip 120, and the sealing material 150 may cover the semiconductor chip 120 and the underfill. The term “fill” (or “filling,” “filled,” or like terms), as may be used herein, is intended to refer broadly to either completely filling a defined space (e.g., the space between the first redistribution substrate 110 and the semiconductor chip 120) or partially filling the defined space; that is, the defined space need not be entirely filled but may, for example, be partially filled or have voids or other spaces throughout.

The sealing material 150 may include an insulating material, for example, a thermosetting resin such as an epoxy resin, a thermoplastic resin such as polyimide, or a resin including a reinforcing material in the above resin. For example, the sealing material 150 may include ABF, FR-4, a BT resin, or the like. Also, the sealing material 150 may include a photosensitive material such as a photo-imageable encapsulant (PIE). The material of the sealing material 150 is not limited to the above materials.

The second redistribution substrate 140 may be on the through post 130 and the sealing material 150. The second redistribution substrate 140 may have a similar structure as that of the first redistribution substrate 110. For example, the second redistribution substrate 140 may include a second body insulating layer 141, the second redistribution line 143, a second vertical via 145, and a second substrate pad 147. The second body insulating layer 141, the second redistribution line 143, and the second vertical via 145 are as respectively described with respect to the first body insulating layer 101, the first redistribution line 103, and the first vertical via 105 of the first redistribution substrate 110. However, the second body insulating layer 141 may be thinner than the first body insulating layer 101. Also, the number of layers of the second redistribution line 143 may be less than the number of layers of the first redistribution line 103. For example, in the semiconductor package 100 of the embodiment, the first redistribution line 103 may have three or more layers, and the second redistribution line 143 may have two layers. However, the numbers of layers of the first redistribution line 103 and the second redistribution line 143 are not limited to the values stated above.

In the second redistribution substrate 140, the second substrate pad 147 may be on an upper surface of the second body insulating layer 141. However, according to some embodiments, the second substrate pad 147 may also be arranged on a lower surface of the second body insulating layer 141. For example, the second substrate pad 147 may be formed on the through post 130, and the second redistribution line 143 may be connected to the second substrate pad 147 through the second vertical via 145.

In the semiconductor package 100 of the embodiment, the second substrate pad 147 may include two or more types of pads. For example, the second substrate pad 147 may include a first-type pad 147a and a second-type pad 147b. The first-type pad 147a may be in a first pad region A in a central portion of the second redistribution substrate 140. The second-type pad 147b may be in a second pad region B in an outer portion of the second redistribution substrate 140. As shown in FIG. 1A, the second pad region B may surround the first pad region A. For reference, the first pad region A may be referred to as a marking pad region in the meaning of having marking for package information formed therein. Also, the second pad region B may be referred to as a joint pad region in the meaning of being coupled to a through post.

As shown in FIG. 2A, in the semiconductor package 100 of the embodiment, a first open hole (i.e., opening) OP1 may be formed in the first pad region A. The first open hole OP1 may penetrate (i.e., extend at least partially into) an upper portion of the second body insulating layer 141 to expose a portion of an uppermost second redistribution line 143T among the second redistribution lines 143. The term “expose” (or “exposed,” or like terms) may be used to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. Also, a second open hole (i.e., opening) OP2 may be formed in the second pad region B. The second open hole OP2 may penetrate an upper portion of the second body insulating layer 141 to expose a portion of the uppermost second redistribution line 143T. Generally, the size of the first open hole OP1 in the first pad region A may be greater than the size of the second open hole OP2 in the second pad region B.

The first-type pad 147a may be on the uppermost second redistribution line 143T in the first open hole OP1. The first-type pad 147a may have a plate shape, as shown in FIG. 2A. Also, the first-type pad 147a may have a smaller size than that of a portion of the uppermost second redistribution line 143T, which is exposed in the first open hole OP1. That is, a horizontal cross-sectional area of the first-type pad 147a may be equal to or less than a horizontal cross-sectional area of the exposed portion of the uppermost second redistribution line 143T. Accordingly, the uppermost second redistribution line 143T may be exposed to the outside of the first-type pad 147a; that is, the uppermost second redistribution line 143T may extend in the x direction beyond the first-type pad 147a. The sizes of the first open hole OP1, the uppermost second redistribution line 143T, and the first-type pad 147a are described in more detail below with reference to FIG. 3.

The second-type pad 147b may be on the uppermost second redistribution line 143T in the second open hole OP2. The second-type pad 147b may include an outer protruding portion OP, as shown in FIG. 2A. That is, the second-type pad 147b may include a central pad portion CP in the central portion thereof and the outer protruding portion OP. The central pad portion CP may be in contact with the uppermost second redistribution line 143T. The outer protruding portion OP may have a structure extending from the central pad portion CP to protrude on the upper surface of the second body insulating layer 141. The second-type pad 147b may fill the inside of the second open hole OP2. Accordingly, in the second open hole OP2, the uppermost second redistribution line 143T may not be exposed.

In the semiconductor package 100 of the embodiment, the uppermost second redistribution line 143T may have a double-metal-layered structure. For example, the uppermost second redistribution line 143T may include a lower metal layer 143d and an upper metal layer 143u. In the semiconductor package 100 of the embodiment, the lower metal layer 143d may include Cu and the upper metal layer 143u may include nickel (Ni). However, the material of the upper metal layer 143u is not limited to Ni. For example, in some embodiments, the upper metal layer 143u may include Ti, TiN, or the like. Also, in some embodiments, the upper metal layer 143u may have a multi-layered structure. For example, the upper metal layer 143u may include Ni/Ti, Ni/TiN, Ti/TiN, or the like.

In the semiconductor package 100 of the embodiment, as the uppermost second redistribution line 143T has a double-metal-layered structure, defects such as discoloration of the first pad region A and the second pad region B, peeling of the second body insulating layer 141 from metal layers such as the uppermost second redistribution line 143T, cracks of the uppermost second redistribution line 143T, or the like may be prevented. Prevention of defects of the semiconductor package 100 of the embodiment is described in more detail with reference to FIG. 4.

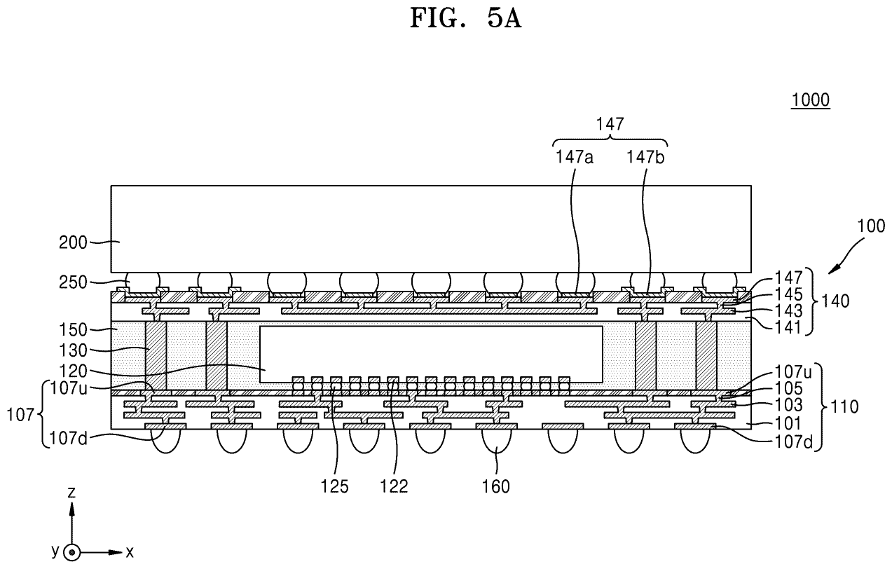

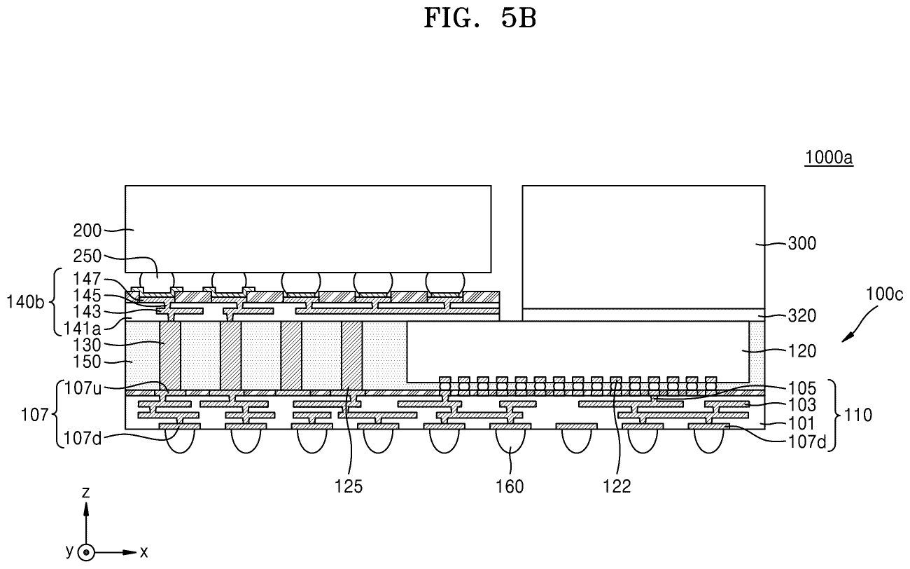

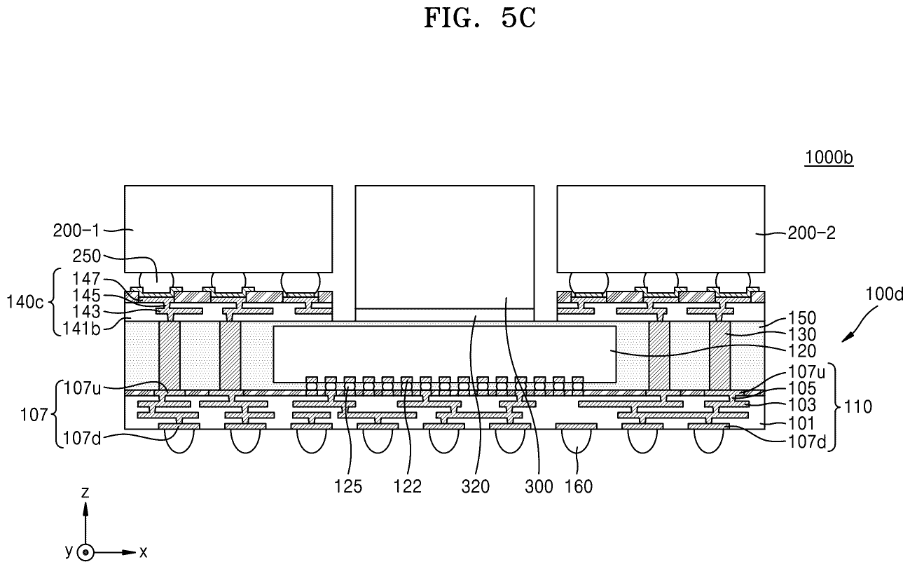

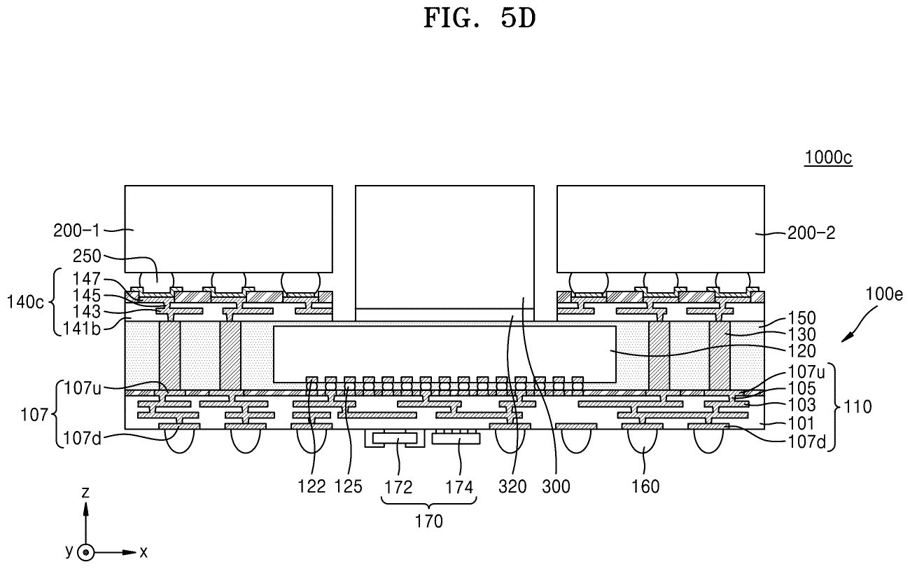

The second redistribution line 143 of the second redistribution substrate 140 may be electrically connected to the semiconductor chip 120 and/or the external connection terminal 160 through the through post 130 and the first redistribution line 103 of the first redistribution substrate 110. Also, when an upper package 200 (refer to FIG. 5A) is on the second redistribution substrate 140, the upper package 200 may be electrically connected to the semiconductor chip 120 and/or the external connection terminal 160 through the second redistribution substrate 140, the through post 130, and the first redistribution substrate 110.

The external connection terminal 160 may be on the first lower substrate pad 107d on the lower surface of the first redistribution substrate 110 and be electrically connected to the first redistribution line 103 through the first lower substrate pad 107d. The external connection terminal 160 may connect the semiconductor package 100 to a package substrate of an external system, or a main board of an electronic device such as a mobile device, or the like (not explicitly shown). The external connection terminal 160 may include a conductive material, for example, at least one of a solder, tin (Sn), silver (Ag), Cu, and aluminum (Al).

The upper package 200 (refer to FIG. 5A) including a memory chip may be stacked on the upper surface of the second redistribution substrate 140 and electrically connected to the second redistribution substrate 140 through an inter-substrate connection terminal 250 (refer to FIG. 5A). A structure of a semiconductor package in which an upper package is stacked on the second redistribution substrate 140 may correspond to a package-on-package (POP) structure. A semiconductor package of a POP structure is described in more detail with reference to the descriptions of FIGS. 5A to 5D. According to embodiments, a heat dissipation structure 300 (refer to FIG. 5B) may also be stacked on the upper surface of the second redistribution substrate 140. Such a semiconductor package structure is described in more detail with reference to the descriptions of FIGS. 5B to 5D.

Referring to FIG. 3, in the semiconductor package 100 of the embodiment, the sizes of the first open hole OP1, the uppermost second redistribution line 143T, and the first-type pad 147a may have the following relationship. For example, a horizontal cross-sectional area of the first open hole OP1 may be less than a horizontal cross-sectional area of the uppermost second redistribution line 143T. For example, a first width W1 of the first open hole OP1 in an x direction may be less than a second width W2 of the uppermost second redistribution line 143T in the x direction. Accordingly, an outer portion of the uppermost second redistribution line 143T may be covered by the second body insulating layer 141. The first width W1 of the first open hole OP1 may be defined as a width in the x direction of a bottom surface of the first open hole OP1. The first width W1 of the first open hole OP1 may be greater than a third width W3 of the first-type pad 147a in the x direction. Accordingly, the first-type pad 147a may have a non-solder mask defined (NSMD) pad structure.

For reference, a pad structure may be divided into a solder mask defined (SMD) pad structure and an NSMD pad structure. The SMD structure may mean a structure in which an outer portion of a pad is covered by a solder mask or a body insulating layer. On the contrary, the NSMD pad structure may refer to a structure in which a pad is separated from a solder mask or a body insulating layer and is completely exposed. In the NSMD pad structure, redistribution lines may be exposed around a pad.

In the semiconductor package 100 of the embodiment, the upper metal layer 143u of the uppermost second redistribution line 143T may have a first cross-sectional thickness D1 (in a z direction) of about 0.1 micrometers (μm) or more. The upper metal layer 143u may function as a barrier film. When the upper metal layer 143u has a cross-sectional thickness less than about 0.1 μm, the upper metal layer 143u may not sufficiently function as a barrier film. Also, in the semiconductor package 100 of the embodiment, the first thickness D1 of the upper metal layer 143u of the uppermost second redistribution line 143T may be equal to or less than a second cross-sectional thickness D2 (in the z direction) of the lower metal layer 143d.

In the semiconductor package 100 of the embodiment, the second substrate pad 147 is arranged on the second redistribution substrate 140, but the second substrate pad 147 may include two types of pads. In particular, the second substrate pad 147 may include the first-type pad 147a arranged in the first pad region A of the second redistribution substrate 140 and the second-type pad 147b arranged in the second pad region B of the second redistribution substrate 140 (see FIGS. 2A-2B). For example, the first-type pad 147a may have an NSMD pad structure and the second-type pad 147b may have an SMD pad structure. In addition, the second-type pad 147b may be classified as an SMD pad structure in an aspect of not being spaced apart from the second body insulating layer 141. However, when considering that the outer portion of the second-type pad 147b is not covered by the second body insulating layer 141, according to embodiments, the second-type pad 147b may also be classified as an NSMD pad structure.

Also, in the semiconductor package 100 of the embodiment, the uppermost second redistribution line 143T of the second redistribution substrate 140 may have a double-metal-layered structure. For example, the uppermost second redistribution line 143T may include the lower metal layer 143d including Cu and the upper metal layer 143u including Ni. As such, as the uppermost second redistribution line 143T of the second redistribution substrate 140 has a double-metal-layered structure, defects such as discoloration of the first pad region A and the second pad region B, peeling of the second body insulating layer 141 from metal layers such as the uppermost second redistribution line 143T, cracks of the metal layers such as the uppermost second redistribution line 143T, of the like may be prevented. Also, the double metal layers of the uppermost second redistribution line 143T are formed through a one-step plating process, and process conditions may be optimized. Here, the one-step plating process may mean that an electroplating process is performed through the same equipment. That is, the double metal layers may be formed with different materials through the electroplating process by using the same equipment.

Referring to FIGS. 1A, 1B, and 2B, a semiconductor package 100a of an embodiment may differ from the semiconductor package 100 of FIG. 1B in that a second substrate pad 147′ is in a second redistribution substrate 140a. In particular, in the semiconductor package 100a of the embodiment, the second substrate pad 147′ may include only the first-type pad 147a. Accordingly, the first-type pad 147a may be in both of the first pad region A and the second pad region B of the second redistribution substrate 140a.

Even in the semiconductor package 100a of the embodiment, the uppermost second redistribution line 143T exposed through the first open hole OP1 and the second open hole OP2 may have a double-metal-layered structure in each of the first pad region A and the second pad region B. For example, the uppermost second redistribution line 143T may include the lower metal layer 143d and the upper metal layer 143u. In the semiconductor package 100a of the embodiment, the lower metal layer 143d may include Cu and the upper metal layer 143u may include nickel (Ni). However, the material of the upper metal layer 143u is not limited to Ni.

Referring to FIGS. 1A, 1B, and 2C, a semiconductor package 100b of an embodiment may differ from the semiconductor package 100 of FIG. 1B in that an uppermost second redistribution line 143T1 has a single-metal-layered structure. In particular, in the semiconductor package 100b of the embodiment, the uppermost second redistribution line 143T1 may have a single-metal-layered structure of Cu.

Also in the semiconductor package 100b of the embodiment, the first-type pad 147a may be arranged in the first pad region A and the second-type pad 147b may be arranged in the second pad region B. Accordingly, in the first pad region A, a portion of the uppermost second redistribution line 143T1 may be exposed through the first open hole OP1. Also, in the second pad region B, the second-type pad 147b may completely fill the second open hole OP2, and the uppermost second redistribution line 143T1 may not be exposed.

Referring to FIG. 4, in a semiconductor package Com. of a comparative example, NSMD pads PAD may be in both of the first pad region A and the second pad region B. Also, an uppermost redistribution line RDL on which a pad PAD is arranged may have a single-layered structure. Hereinafter, in the semiconductor package Com. having a structure of the uppermost redistribution line RDL and the pad PAD, defects such as peeling, cracks, or the like may occur. In particular, as Cu of the uppermost redistribution line RDL is exposed through an open hole, defects such as discoloration and peeling may occur due to oxidation of Cu. Here, peeling may mean a phenomenon in which a body insulating layer PID falls off from a metal layer such as the pad PAD and/or the uppermost redistribution line RDL or the like. Also, when a soldering process is performed on the pad PAD, cracks may occur in the metal layer of the pad PAD and/or the uppermost redistribution line RDL due to stress caused by excessive growth of an inter-metallic compound (IMC).

On the contrary, in the semiconductor package 100 of the illustrative embodiment of FIGS. 1A and 1B, as the uppermost second redistribution line 143T includes the upper metal layer 143u of Ni and the lower metal layer 143d of Cu, and the types of pads in the first pad region A and the second pad region B are dualized, the above problems may be solved. For example, in the first pad region A, the first-type pad 147a may be formed in a flat shape on the upper metal layer 143u of Ni and be merged with the uppermost second redistribution line 143T through the upper metal layer 143u. Accordingly, defects of discoloration and peeling (De-La) due to oxidation of Cu may be solved. Also, as the types of pads in the first pad region A and the second pad region B may be dualized and arranged, in the case of the first pad region A, peeling defects may be improved and the amount of the second body insulating layer 141 may be minimized. Also, in the case of the second pad region B, as the second-type pad 147b is on the upper metal layer 143u of Ni and has a structure including the outer protruding portion OP, the excessive growth of the ICM in a soldering process may be suppressed. Accordingly, crack defects in the metal layer such as the second redistribution line 143 may be prevented.

FIGS. 5A to 5D are cross-sectional views each schematically showing at least a portion of an example structure of a semiconductor package according to an embodiment. Descriptions already given with reference to FIGS. 1A to 4 are briefly given or omitted.

Referring to FIG. 5A, a semiconductor package 1000 of an embodiment may differ from the semiconductor package 100 of FIG. 1 in that the upper package 200 is further included. In particular, the semiconductor package 1000 of the embodiment may include a lower package 100 and the upper package 200. The lower package 100 may be consistent with the illustrative semiconductor package 100 of FIG. 1B. However, the lower package 100 is not limited to the semiconductor package 100 of FIG. 1B. For example, the lower package 100 may also be the semiconductor package 100a of FIG. 2B or 100b of FIG. 2C.

The upper package 200 may have, for example, a structure including a package substrate, an upper semiconductor chip, an upper sealing material, or the like. The package substrate may comprise, for example, a ceramic substrate, a printed circuit board (PCB), an organic substrate, an interposer substrate, or the like. In the semiconductor package 1000 of the embodiment, the package substrate may be a PCB. An inter-substrate connection terminal 250, such as a bump or a solder ball, may be on a lower surface of the package substrate. The upper package 200 may be mounted on the second redistribution substrate 140 through the inter-substrate connection terminal 250.

The upper semiconductor chip may be a memory chip, although embodiments are not limited thereto. For example, the upper semiconductor chip may include a volatile memory element such as dynamic random-access memory (DRAM), static random-access memory (SRAM), or the like, or a non-volatile memory element such as flash memory or the like.

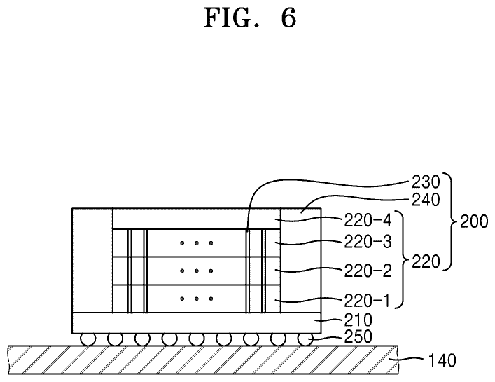

The upper package 200 may have a structure in which one upper semiconductor chip is mounted on the package substrate or may have a structure in which a plurality of upper semiconductor chips are stacked on the package substrate. The plurality of upper semiconductor chips may be mounted on the package substrate through an adhesive layer and a bonding wire or may be mounted on the package substrate by using a bump and a through-silicon via (TSV). For example, in the semiconductor package 1000, the upper package 200 may be a high-bandwidth memory (HBM) package. The HBM package is described in more detail with reference to the descriptions of FIG. 6. According to embodiments, a single chip may be stacked on the second redistribution substrate 140 instead of the upper package 200.

The upper sealing material may protect the upper semiconductor chip from external physical or chemical damage by sealing the upper semiconductor chip. The upper sealing material may include an insulating material, for example, a thermosetting resin such as an epoxy resin, a thermoplastic resin such as polyimide, or a resin including a reinforcing material in the above resin. For example, the upper sealing material may include Ajinomoto Build-Up Film (ABF®, a registered trademark of Ajinomoto Fine-Techno Co., Inc.), FR-4 (an epoxy resin), a bismaleimide triazine (BT) resin, or the like. However, the material of the upper sealing material is not limited to the above materials.

Referring to FIG. 5B, a semiconductor package 1000a of an embodiment may differ from the semiconductor package 1000 of FIG. 5A in that a heat dissipation structure 300 is further stacked on an upper surface of the semiconductor chip 120. In particular, in a lower package 100c of the semiconductor package 1000a of the embodiment, the semiconductor chip 120 may be on the first redistribution substrate 110 but may be arranged biased to the right in an x direction. Also, an upper surface of the semiconductor chip 120 may be exposed from the sealing material 150.

The second redistribution substrate 140b may cover the through post 130 and the sealing material 150 and may cover a portion of the upper surface of the semiconductor chip 120. In other words, on the upper surface of the semiconductor chip 120, the second redistribution substrate 140b and the heat dissipation structure 300 may be arranged laterally adjacent to each other with a certain spacing in the x direction therebetween. The upper package 200 may be stacked on the second redistribution substrate 140b. The upper package 200 may be as described in the descriptions of the semiconductor package 1000 of FIG. 5A.

The heat dissipation structure 300 may be stacked on the semiconductor chip 120 through an adhesive layer 320 (e.g., conductive epoxy), or an alternative attachment means. The heat dissipation structure 300 may be, for example, a heat sink or a heat slug. To efficiently transfer heat from the semiconductor chip 120 to the heat dissipation structure 300, the adhesive layer 320 may include a material with high thermal conductivity. For example, the adhesive layer 320 may include a thermal interface material (TIM), a thermally conductive resin, a thermally conductive polymer, silicon oxide or silicon nitride such as SiO₂ or SiCN, or the like. Here, the TIM may include a material with high thermal conductivity, that is, grease, tape, an elastomer filling pad, a phase change material, or the like, which are materials with low thermal resistance. In the semiconductor package 1000a of the embodiment, as the upper surface of the semiconductor chip 120 is exposed, and the heat dissipation structure 300 is directly stacked on the semiconductor chip 120 via the adhesive layer 320, heat dissipation efficiency may be greatly improved from the semiconductor chip 120.

Referring to FIG. 5C, a semiconductor package 1000b of an embodiment may differ from the semiconductor package 1000a of FIG. 5B in that the heat dissipation structure 300 may be stacked in the z direction on at least a portion of the upper surface of the semiconductor chip 120, and two upper packages 200-1 and 200-2 may be stacked on an upper surface of a second redistribution substrate 140c. In particular, in a lower package 100d of the semiconductor package 1000b of the embodiment, the second redistribution substrate 140c may be divided into two portions, and the upper packages 200-1 and 200-2 may be stacked on corresponding portions of the second redistribution substrate 140c.

The heat dissipation structure 300 may be arranged between the two upper packages 200-1 and 200-2 in the x direction. Also, the heat dissipation structure 300 may be directly stacked on the upper surface of the semiconductor chip 120 through the adhesive layer 320. The heat dissipation structure 300 and the adhesive layer 320 are as described in the descriptions with reference to the semiconductor package 1000a of FIG. 5B.

According to embodiments, the second redistribution substrate 140c may have a rectangular ring shape, when viewed in a plan view, with only a central portion thereof removed. In the structure of the second redistribution substrate 140c, four upper packages may be arranged on each side of the rectangular ring shape.

Referring to FIG. 5D, a semiconductor package 1000c of an embodiment may differ from the semiconductor package 1000b of FIG. 5C in that a passive element 170 is further included. In particular, in a lower package 100e of the semiconductor package 1000c of the embodiment, the passive element 170 may be on a lower surface of the first redistribution substrate 110. According to some embodiments, the passive element 170 may, alternatively or in addition to, be arranged on the upper surface of the first redistribution substrate 110 and/or inside the first redistribution substrate 110. Also, the passive element 170 may be on a lower surface, an upper surface, and/or inside a second redistribution substrate 140c. The passive element 170 may include a two-terminal element such as, for example, a resistor, an inductor, or a capacitor. In the semiconductor package 1000c of the embodiment, the passive element 170 may include a multi-layer ceramic capacitor (MLCC) 172 and a Si-capacitor 174.

FIG. 6 is a cross-sectional view showing in more detail a structure of an upper package in the semiconductor package 1000 of FIG. 5A, and the second redistribution substrate 140 is schematically illustrated for convenience. Description is made with reference to FIG. 5A together, and descriptions already given with reference to FIGS. 1A to 5D are briefly given or omitted.

Referring to FIG. 6, as described above, in the semiconductor package 1000 of FIG. 5A, the upper package 200 may be an HBM package. In more particular, the upper package 200 may include a base chip 210 and a plurality of core chips 220-1, 220-2, 220-3 and 220-4 (collectively 220) on the base chip 210. Also, the base chip 210 and the plurality of core chips 220 may include a through electrode 230 therein. An uppermost core chip 220-4 among the plurality of core chips 220 may not include the through electrode 230.

The base chip 210 may include logic elements, although embodiments are not limited thereto. Accordingly, the base chip 210 may be a logic chip. The base chip 210 may be below the plurality of core chips 220 to integrate signals from the plurality of core chips 220 and transmit the integrated signal to the outside and may also transmit signals and power from the outside to the plurality of core chips 220. Accordingly, the base chip 210 may be referred to as a buffer chip or a control chip. Each of the plurality of core chips 220 may be a memory chip. For example, each of the plurality of core chips 220 may be a DRAM chip. A core chip may be stacked on the base chip 210 or a core chip 220 therebelow through pad-to-pad bonding, hybrid bonding, bonding using a bonding member, bonding using an anisotropic conductive film (ACF), or the like. In FIG. 6, four core chips 220-1 through 220-4 are stacked, but the number of core chips 220 is not limited to four. For example, three or less or five or more core chips 220 may be stacked.

The inter-substrate connection terminal 250 may be on a lower surface of the base chip 210. The inter-substrate connection terminal 250 may include, for example, a pillar and a solder, or may include only a solder (e.g., solder bump). The inter-substrate connection terminal 250 may be connected to the through electrode 230. The upper package 200 may be provided on the second redistribution substrate 140 through the inter-substrate connection terminal 250. The core chips 220 on the base chip 210 may be sealed by an upper sealing material (e.g., encapsulant) 240. However, the uppermost core chip 220-4 among the plurality of core chips 220 may not be covered by the upper sealing material 240. However, in other embodiments, an upper surface of the uppermost core chip 220-4 may also be covered by the upper sealing material 240.

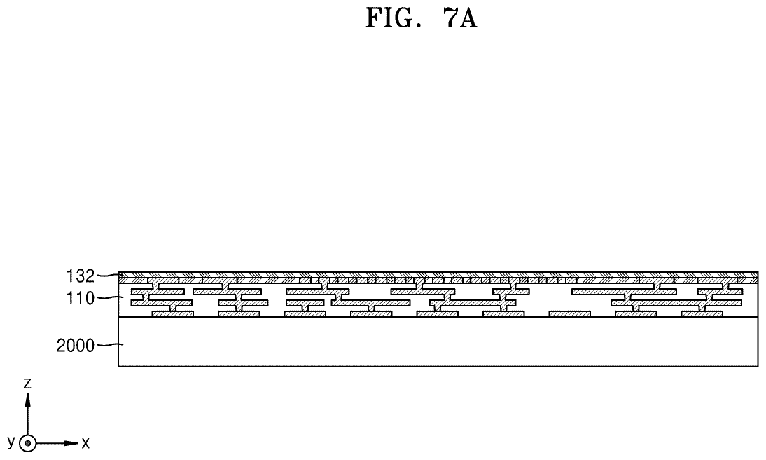

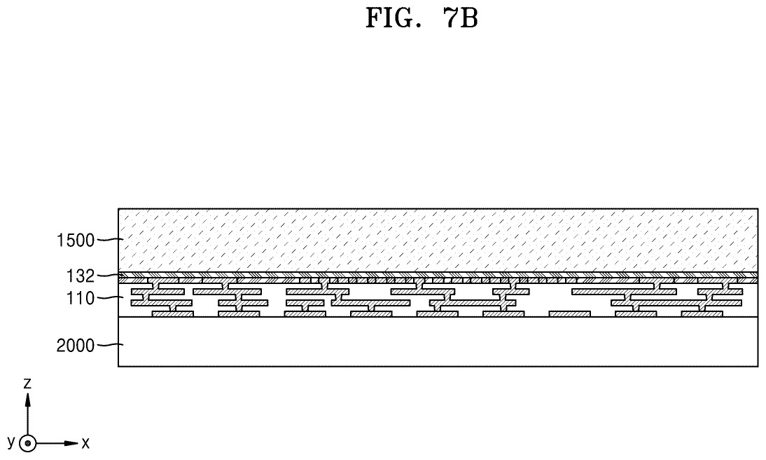

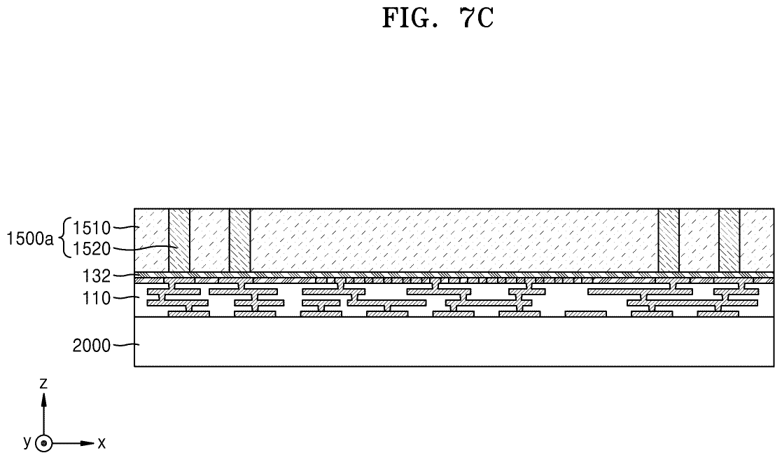

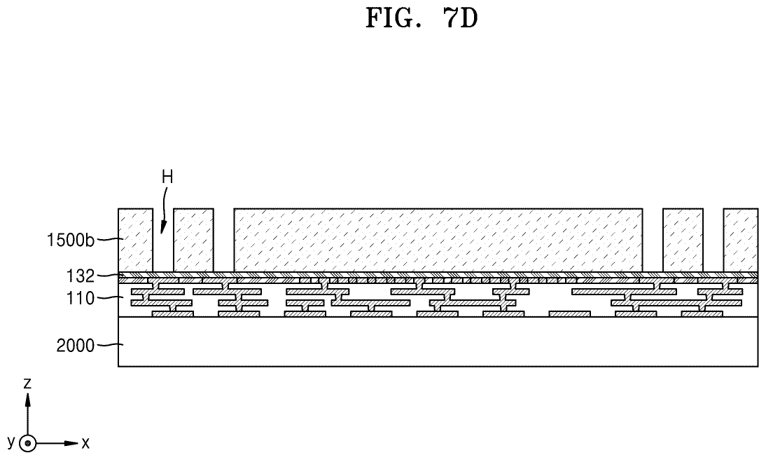

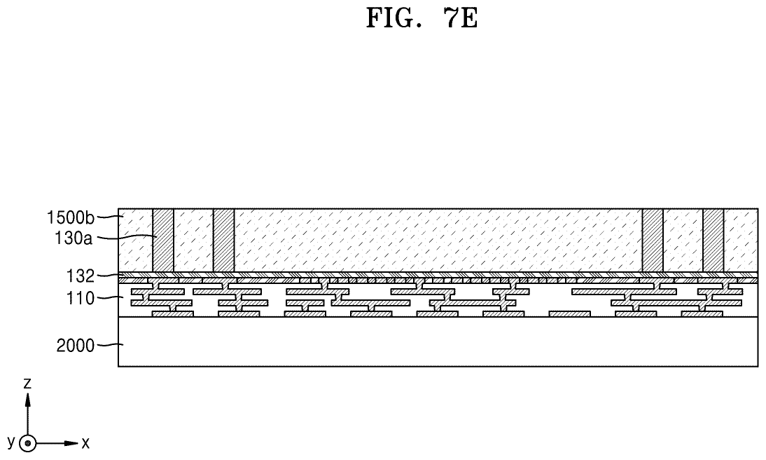

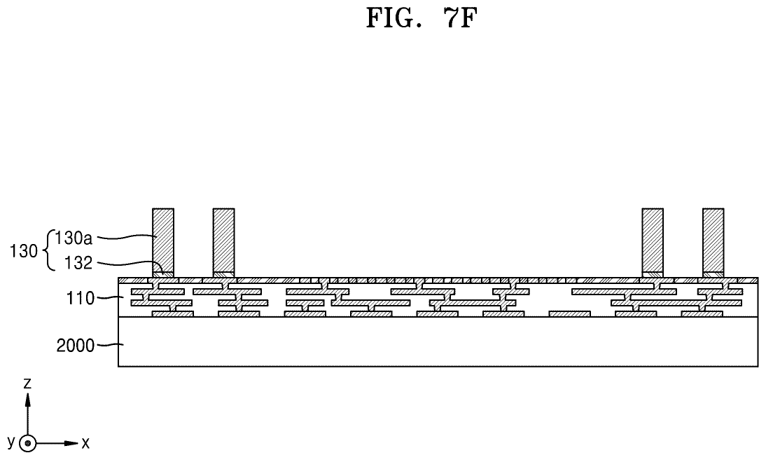

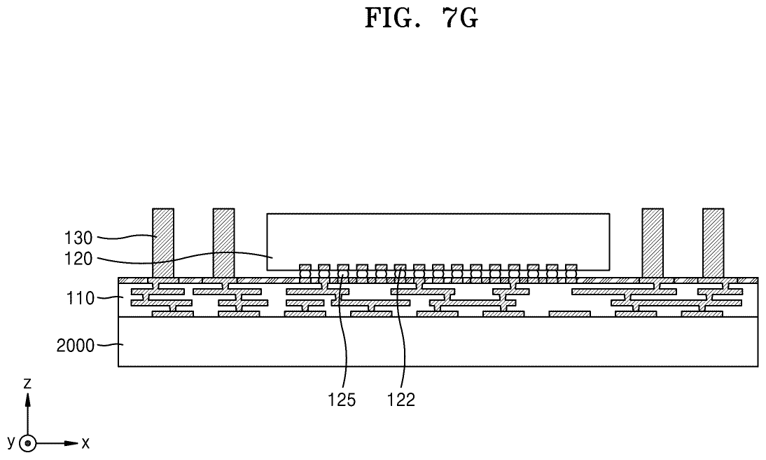

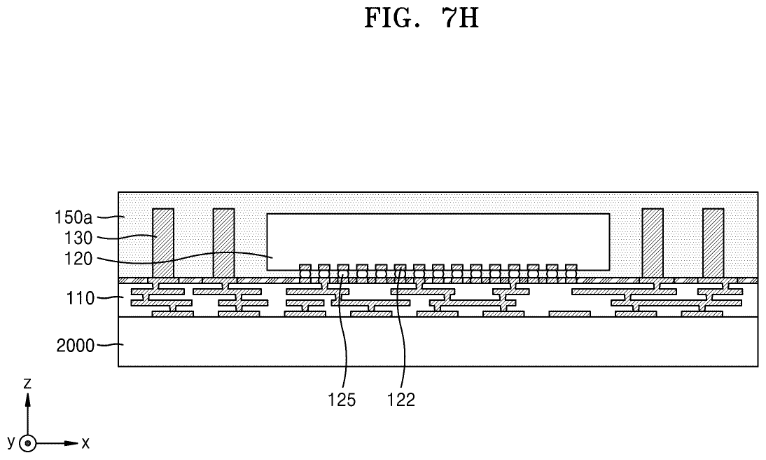

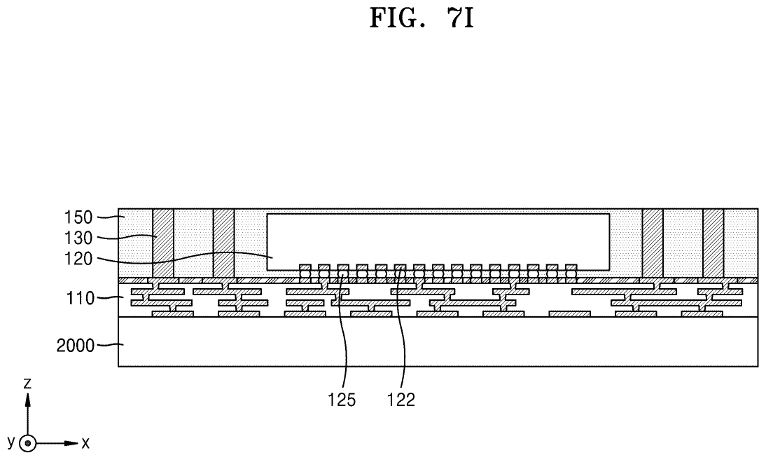

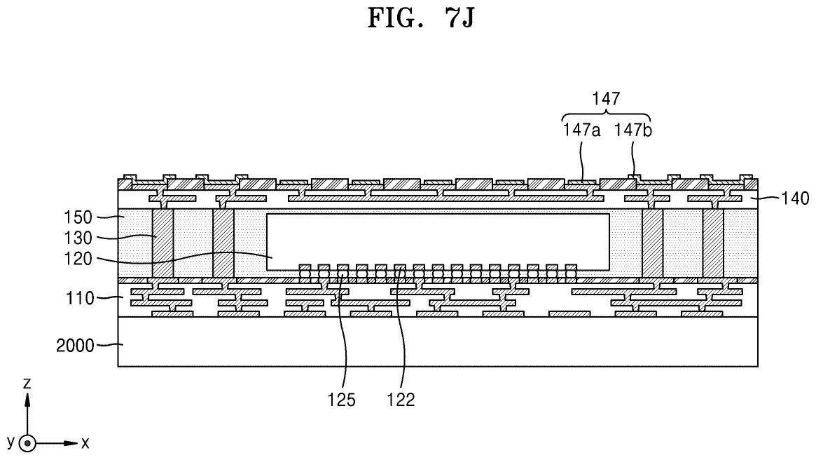

FIGS. 7A to 7J are cross-sectional views schematically showing intermediate processes in an example operation of manufacturing the semiconductor package 100 of FIG. 1B. Description is made with reference to FIG. 1B together, and descriptions already given with reference to FIGS. 1A to 6 are briefly given or omitted.

Referring to FIG. 7A, in a method of manufacturing the semiconductor package 100 of the embodiment, firstly, the first redistribution substrate 110 is formed. The first redistribution substrate 110 may include the first body insulating layer 101, the first redistribution line 103, the first vertical via 105, and the first substrate pad 107, as described above (see FIG. 1B). The first redistribution substrate 110 may be on a carrier substrate 2000. The carrier substrate 2000 may be a large-sized substrate, such as a wafer. Also, a large redistribution substrate including a plurality of first redistribution substrates 110 may be formed on the carrier substrate 2000. After subsequent components are formed on the large redistribution substrate, a semiconductor package individualized (i.e., diced) through a sawing process is referred to as a WLP (wafer level packaging). However, for convenience of description, only one first redistribution substrate 110 and components corresponding thereto are shown in FIGS. 7A and FIGS. 7B to 7J below.

Thereafter, a seed metal 132 is formed on the first redistribution substrate 110. The seed metal 132 may be used in a subsequent electroplating process for forming the through post 130. The seed metal 132 may include one or more of various metal materials, for example, Cu, Ti, Ta, TiN, TaN, or the like. In the method of manufacturing a semiconductor package of the embodiment, the seed metal 132 may include Cu.

Referring to FIG. 7B, a photoresist (PR) 1500 is coated on the seed metal 132 of the first redistribution substrate 110. The PR 1500 may be coated, for example, through a spin coating method using a spin coater. The PR 1500 may be formed to have a cross-sectional thickness (in the z direction) corresponding to a height of the through post 130 (FIG. 1B).

Referring to FIG. 7C, after the PR 1500 is coated on the seed metal 132 of the first redistribution substrate 110, an exposure process is performed. The exposure process may be performed by using a mask including a particular pattern. For example, light may pass through a transparent portion of a transparent mask, and light may be irradiated on a certain portion of the PR 1500. Chemical properties of the portion of the PR 1500, which is irradiated with light, may be changed. For example, after the exposure process, a PR 1500a may be divided into an unexposed portion 1510 and an exposed portion 1520. As can be seen in FIG. 7C, the exposed portion 1520 may be positioned at an outer portion (i.e., periphery) of the first redistribution substrate 110.

Referring to FIG. 7D, after the exposure process, a development process is performed on the PR 1500a. In the development process, for example, the exposed portion 1520 may be removed. For example, the PR 1500a may be a positive PR. According to embodiments, a negative PR may also be used, and when the negative PR is used, the unexposed portion of the PR 1500a may be removed.

As the exposed portion 1520 is removed through the development process, a PR pattern 1500b may be formed on the seed metal 132. The PR pattern 1500b may include a plurality of through holes H. The seed metal 132 may be exposed from bottom surfaces of the plurality of through holes H. After the development process, by-products such as PR scum or the like may remain in the plurality of through holes H. Accordingly, the by-products are removed through a cleaning process. For reference, a process of removing PR scum is referred to as a PR descum process. The PR descum process may be included in the cleaning process.

Referring to FIG. 7E, after the cleaning process, a through post 130a is formed inside the plurality of through holes H through electroplating. The through post 130a may include, for example, Cu. Although not shown in the drawing, the through post 130a may also be formed on a portion of an upper surface of the PR pattern 1500b adjacent to the through hole H.

Referring to FIG. 7F, after the through post 130a is formed, the PR pattern 1500b (see FIG. 7E) is removed. The PR pattern 1500b may be removed through an ashing/strip process. After the PR pattern 1500b is removed, the seed metal 132 may be exposed between the through posts 130a. Subsequently, the seed metal 132 exposed between the through posts 130a is removed through an etching process. An upper surface of the first redistribution substrate 110 may be exposed between the through posts 130a through the removal of the exposed seed metal 132. The seed metal 132 on the lower surface of the through post 130a may remain as the seed metal 132. The seed metal 132 and the through post 130a may include the same Cu. Accordingly, the seed metal 132 and the through post 130a are together referred to as the through post 130, and the seed metal 132 is omitted from FIGS. 7G to 7J below.

Referring to FIG. 7G, the semiconductor chip 120 of FIG. 1B is provided on the first redistribution substrate 110. The semiconductor chip 120 may be attached on the first redistribution substrate 110 in a flip-chip structure by using the bumps 125. The bumps 125 may contact corresponding pads 122 on the front surface of the semiconductor chip 120, which is flipped upside down. According to embodiments, an underfill may fill a space between the first redistribution substrate 110 and the semiconductor chip 120 and between the bumps 125.

Referring to FIG. 7H, after the semiconductor chip 120 is provided on the first redistribution substrate 110, a sealing material 150a (i.e., encapsulant) covering the semiconductor chip 120 and the through post 130 is formed on the first redistribution substrate 110. The sealing material 150a may cover side and upper surfaces of the semiconductor chip 120 and side and upper surfaces of the through post 130. The material of the sealing material 150a is as described with reference to the sealing material 150 of the semiconductor package 100 of FIG. 1B.

Referring to FIG. 7I, a planarization process of removing an upper portion of the sealing material 150a is performed. The planarization process may be performed through a grinding and/or chemical mechanical polishing (CMP) process. Through the planarization process of the sealing material 150a, an upper surface of the through post 130 may be exposed through the sealing material 150. After the planarization process of the sealing material 150a, the upper surface of the through post 130 and an upper surface of the sealing material 150 may be substantially coplanar in the z direction. As shown in FIG. 7I, the sealing material 150 having a certain thickness in the z direction may remain on an upper portion of the semiconductor chip 120.

Referring to FIG. 7J, after the planarization process, the second redistribution substrate 140 is formed on the through post 130 and the sealing material 150. The second redistribution substrate 140 may include the second body insulating layer 141, the second redistribution line 143, the second vertical via 145, and the second substrate pad 147 (see FIG. 1B). The second redistribution line 143 of the second redistribution substrate 140 may be connected to the through post 130. Besides, the second redistribution substrate 140 is as described with reference to the second redistribution substrate 140 of the semiconductor package 100 of FIG. 1B.

Thereafter, the carrier substrate 2000 is separated from the first redistribution substrate 110, and the external connection terminal 160 is arranged on the lower surface of the first redistribution substrate 110, as shown in FIG. 1B. The semiconductor package 100 of FIG. 1B may be complemented through the arrangement of the external connection terminal 160. As described above, because the processes of FIGS. 7A to 7J are formed at a wafer level, the semiconductor package 100 of FIG. 1B may be substantially completed through a sawing process of separating a semiconductor package into individual semiconductor packages.

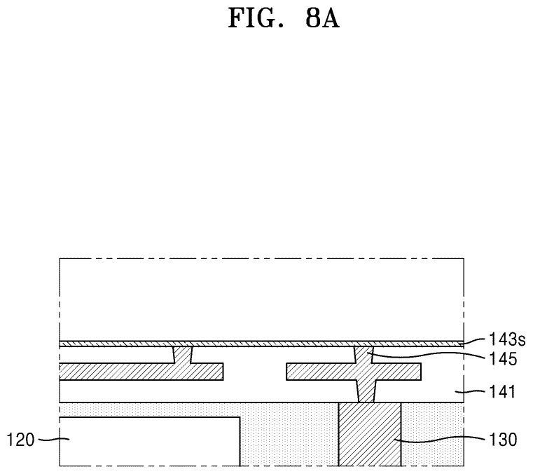

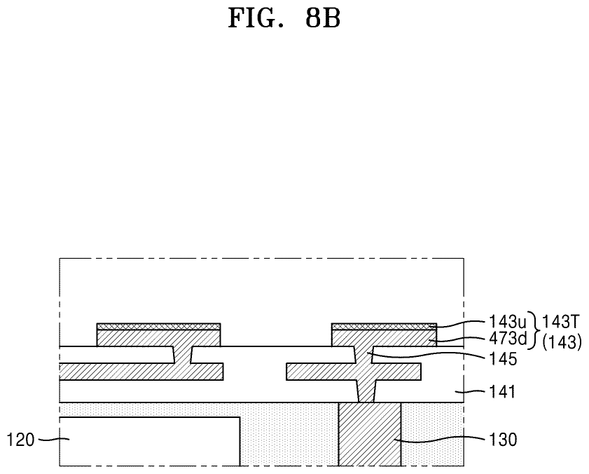

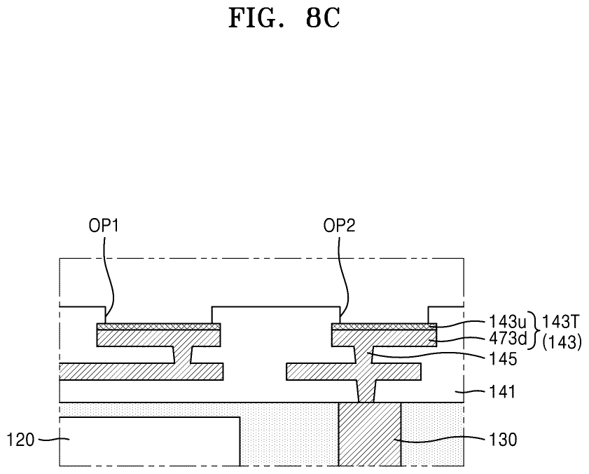

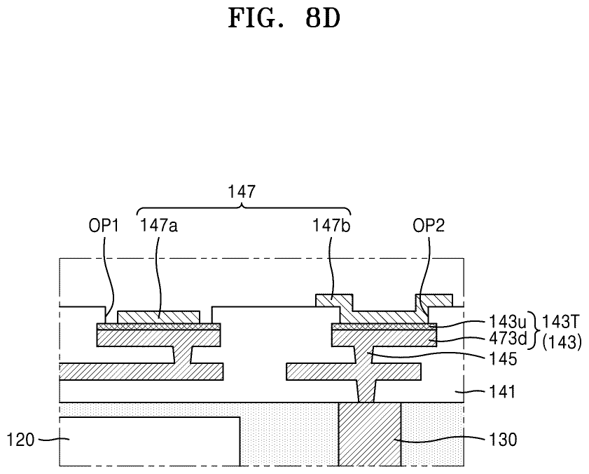

FIGS. 8A to 8D are cross-sectional views showing in more detail intermediate processes in an example method of manufacturing a second redistribution substrate 140 of FIG. 7J, which may correspond to the cross-sectional view of FIG. 2A. Description is made with reference to FIG. 2A together, and descriptions already given with reference to FIGS. 1A to 7J are briefly given or omitted.

Referring to FIG. 8A, a process of forming the second redistribution substrate 140 includes coating a seed metal and coating the second body insulating layer 141 of the PID on the seed metal. Thereafter, after the second body insulating layer 141 is patterned through an exposure process, the second redistribution line 143 and/or the second vertical via 145 may be formed through an electroplating process. Such a process may also be performed for each layer. FIG. 8A shows a state in which a seed metal 143s is formed on the second body insulating layer 141 and the second vertical via 145 after the second redistribution line 143 and the second vertical via 145 of a lower layer are formed.

Referring to FIG. 8B, the second body insulating layer 141 of the PID is coated on the seed metal 143s, and the second body insulating layer 141 is patterned through a photo process to expose the seed metal 143s. Subsequently, an electroplating process is performed on the seed metal 143s to form the uppermost second redistribution line 143T on the second vertical via 145. Thereafter, the second body insulating layer 141 is removed to expose the seed metal 143s. Subsequently, the exposed seed metal 143s is removed. The uppermost second redistribution line 143T may include, for example, the lower metal layer 143d of Cu and the upper metal layer 143u of Ni. Meanwhile, the lower metal layer 143d may include seed metal at the bottom. The uppermost second redistribution line 143T may be formed through a one-step electroplating process.

Referring to FIG. 8C, after forming the uppermost second redistribution line 143T, an uppermost portion of the second body insulating layer 141 covering the uppermost second redistribution line 143T is formed. Thereafter, first and second open holes (i.e., openings) OP1 and OP2 each exposing a portion of an upper surface of the uppermost second redistribution line 143T are formed through a photo process. For example, the first open hole OP1 may be formed in the first pad region A and the second open hole OP2 may be formed in the second pad region B. As shown, the first open hole OP1 may be formed to be relatively greater in width than the second open hole OP2. For example, the first and second open holes OP1 and OP2 each exposing the uppermost second redistribution line 143T may be dualized and formed according to pad regions.

Referring to FIG. 8D, after the first and second open holes OP1 and OP2 are formed, a seed metal is formed on an upper surface and an inner wall of the second body insulating layer 141 and on the uppermost second redistribution line 143T, which is exposed. Subsequently, a portion where a pad will be formed is defined through PR coating and patterning. Thereafter, the second substrate pad 147 is formed through electroplating. As described above, the second substrate pad 147 may include the first-type pad 147a in the first open hole OP1 in the first pad region A and the second-type pad 147b in the second open hole OP2 in the second pad region B. As shown, the first-type pad 147a may have a flat shape, and the second-type pad 147b may have a structure including the outer protruding portion OP which extends onto the upper surface of the second body insulating layer 141 proximate sidewalls defining the second open hole OP2.

While the inventive concept has been particularly shown and described with reference to embodiments thereof, it will be understood that various changes in form and details may be made therein without departing from the spirit and scope of the following claims.

1. A semiconductor package, comprising:
a first redistribution substrate having a multi-layered first redistribution line;
a semiconductor chip on the first redistribution substrate;
a through post extending vertically on the first redistribution substrate and spaced laterally from the semiconductor chip; and
a second redistribution substrate on the semiconductor chip and the through post and having at least one multi-layered second redistribution line,
wherein a first pad region and a second pad region are defined on an upper surface of the second redistribution substrate, the first pad region including a first opening exposing a first portion of the at least one second redistribution line and positioned at a central portion of the second redistribution substrate, and the second pad region extending around the first pad region and including a second opening exposing a second portion of the at least one second redistribution line,
a first-type pad having a planar shape is on the at least one second redistribution line in the first opening, and a second-type pad having an outer protruding portion is on the at least one second redistribution line in the second opening.

2. The semiconductor package of claim 1, wherein
an uppermost second redistribution line of the at least one second redistribution line exposed from the first opening and the second opening has a multi-metal-layered structure,
the uppermost second redistribution line comprises a lower metal layer of copper (Cu) and an upper metal layer of nickel (Ni) and/or an upper metal layer of titanium (Ti), and
the first-type pad and the second-type pad are on the upper metal layer.

3. The semiconductor package of claim 2, wherein
the uppermost second redistribution line comprises the lower metal layer of Cu and the upper metal layer of Ni,
a first cross-sectional thickness of the upper metal layer is about 0.1 μm or more, and
the lower metal layer has a second cross-sectional thickness equal to or greater than the first cross-sectional thickness of the upper metal layer.

4. The semiconductor package of claim 1, wherein
the first-type pad is on an uppermost second redistribution line of the at least one second redistribution line in the first opening, and
the uppermost second redistribution line is exposed around the first-type pad.

5. The semiconductor package of claim 4, wherein
the second redistribution substrate comprises a body insulating layer over the at least one second redistribution line,
the first opening has a structure extending vertically into a portion of an upper portion of the body insulating layer to expose a portion of the uppermost second redistribution line,
an entirety of the uppermost second redistribution line has a first width in a first direction parallel to an upper surface of the first redistribution substrate,
a portion of the uppermost second redistribution line, which is exposed through the first opening, has a second width that is less than the first width in the first direction, and
the body insulating layer is over an outer portion of the uppermost second redistribution line.

6. The semiconductor package of claim 1, wherein
the second-type pad is on an uppermost second redistribution line of the at least one second redistribution line in the second opening, and
the uppermost second redistribution line is not exposed around the second-type pad.

7. The semiconductor package of claim 6, wherein
the second redistribution substrate comprises a body insulating layer over the at least one second redistribution line,
the second opening has a structure extending vertically into a portion of an upper portion of the body insulating layer and having a bottom surface of the uppermost second redistribution line and side surfaces of the body insulating layer, and
the second-type pad has a structure extending from the uppermost second redistribution line onto the side surfaces and an upper surface of the body insulating layer.

8. The semiconductor package of claim 7, wherein a portion of the second-type pad extending onto the upper surface of the body insulating layer constitutes the outer protruding portion of the second-type pad.

9. The semiconductor package of claim 1, further comprising
an upper package on the second redistribution substrate,
wherein the semiconductor chip comprises an application processor (AP) chip, and
the upper package comprises at least one memory chip.

10. The semiconductor package of claim 1, further comprising
a sealing material at least partially filling a space between the first redistribution substrate and the second redistribution substrate and on the semiconductor chip,
wherein the through post extends into the sealing material and electrically connects the first redistribution substrate to the second redistribution substrate.

11. A semiconductor package, comprising:
a first redistribution substrate having a multi-layered first redistribution line;
a semiconductor chip on the first redistribution substrate;
a sealing material on the first redistribution substrate and over the semiconductor chip;
a through post on the first redistribution substrate extending into the sealing material and spaced laterally from the semiconductor chip;
a second redistribution substrate on the sealing material and having at least one second redistribution line; and
an upper package on the second redistribution substrate and electrically connected to the second redistribution substrate through an inter-substrate connection terminal,
wherein an opening exposing a portion of the multi-layered second redistribution line is on an upper surface of the second redistribution substrate, and
an uppermost second redistribution line of the at least one second redistribution line exposed through the opening has a multi-metal-layered structure.

12. The semiconductor package of claim 11, wherein
a first pad region and a second pad region are defined on the upper surface of the second redistribution substrate, the first pad region positioned at a central portion of the second redistribution substrate, and the second pad region extending around the first pad region,
the opening comprises a first opening in the first pad region and a second opening in the second pad region,
a first-type pad having a planar shape is on the uppermost second redistribution line of the at least one second redistribution line in the first opening, and
a second-type pad having an outer protruding portion is on the uppermost second redistribution line of the at least one second redistribution line in the second opening.

13. The semiconductor package of claim 12, wherein
the uppermost second redistribution line of the at least one second redistribution line comprises a lower metal layer of copper (Cu) and an upper metal layer of nickel (Ni),
the first-type pad is on the upper metal layer in the first opening, and
the upper metal layer is exposed around the first-type pad.

14. The semiconductor package of claim 12, wherein
the uppermost second redistribution line of the at least one second redistribution line comprises a lower metal layer of copper (Cu) and an upper metal layer of nickel (Ni),
the second-type pad is on the upper metal layer in the second opening, and
the upper metal layer is not exposed around the second-type pad.

15. The semiconductor package of claim 14, wherein
the second redistribution substrate comprises a body insulating layer on the at least one second redistribution line,
the second opening has a structure extending vertically into a portion of an upper portion of the body insulating layer and defined by a bottom surface of the upper metal layer and side surfaces of the body insulating layer, and
the second-type pad has a structure extending from the upper metal layer onto the side surfaces and an upper surface of the body insulating layer.

16. A semiconductor package, comprising:
a first redistribution substrate having a multi-layered first redistribution line;
a semiconductor chip on the first redistribution substrate;
a through post on the first redistribution substrate and spaced laterally from the semiconductor chip; and
a second redistribution substrate on the semiconductor chip and the through post and having at least one second redistribution line,
wherein an opening exposing a portion of the at least one second redistribution line is on an upper surface of the second redistribution substrate, and
an uppermost second redistribution line of the at least one second redistribution line exposed through the opening comprises a lower metal layer of copper (Cu) and an upper metal layer of nickel (Ni).

17. The semiconductor package of claim 16, wherein
a first pad region and a second pad region are defined on the upper surface of the second redistribution substrate, the first pad region at a central portion of the second redistribution substrate, and the second pad region extending around the first pad region,
the opening comprises a first opening in the first pad region and a second opening in the second pad region,
a first-type pad having a planar shape is on the uppermost second redistribution line of the at least one second redistribution line in the first opening, and
a second-type pad having an outer protruding portion is on the uppermost second redistribution line of the at least one second redistribution line in the second opening.

18. The semiconductor package of claim 17, wherein
the first-type pad is on the upper metal layer in the first opening, and
the upper metal layer is exposed around the first-type pad.

19. The semiconductor package of claim 17, wherein
the second-type pad is on the upper metal layer in the second opening,
the second redistribution substrate comprises a body insulating layer on the second redistribution line of the at least one second redistribution line,
the second opening has a structure extending vertically into a portion of an upper portion of the body insulating layer and defined by a bottom surface of the upper metal layer and side surfaces of the body insulating layer, and
the second-type pad has a structure extending from the upper metal layer onto the side surfaces and an upper surface of the body insulating layer.

20. The semiconductor package of claim 16, further comprising
an upper package on the second redistribution substrate,
wherein the semiconductor chip comprises an application processor (AP) chip, and
the upper package comprises at least one memory chip.

21.-25. (canceled)
